(19) United States
(12) Patent Application Publication
(10) Pub. No.: US 2025/0204037 A1
(43) Pub. Date: Jun. 19, 2025

(54) COMPLEMENTARY FIELD EFFECT TRANSISTOR AND RELATED METHODS

(71) Applicant: Taiwan Semiconductor Manufacturing Co., Ltd., Hsinchu (TW)

(72) Inventors: Hsien-Chih HUANG, Hsinchu (TW); Guan-Lin CHEN, Hsinchu (TW); Pei-Yu WANG, Hsinchu (TW); Chia-Hao YU, Hsinchu (TW); Chih-Hao WANG, Hsinchu (TW)

(21) Appl. No.: 18/740,341

(22) Filed: Jun. 11, 2024

Related U.S. Application Data
(60) Provisional application No. 63/610,370, filed on Dec. 14, 2023.

(51) Int. Cl. H01L 27/092; H01L 21/285; H01L 21/822; H01L 21/8238; H01L 29/06; H01L 29/08; H01L 29/417; H01L 29/423; H01L 29/66; H01L 29/775; H01L 29/786

(52) U.S. Cl. CPC H10D 84/856; H01L 21/28518; H10D 30/014; H10D 30/031; H10D 30/43; H10D 30/6729; H10D 30/6735; H10D 30/6757; H10D 62/121; H10D 62/151; H10D 64/017; H10D 84/0167; H10D 84/017; H10D 84/0186; H10D 84/038; H10D 88/01

(57) ABSTRACT

A device and associated method that includes a plurality of first nanostructures formed in a first stack. The device also includes a plurality of second nanostructures formed in a second stack. The device also includes a first source/drain structure adjacent to the plurality of first nanostructures, the first source/drain structure including a first semiconductor having silicon and germanium. The device also includes a second source/drain structure stacked vertically over the first source/drain structure and adjacent to the plurality of second nanostructures, the second source/drain structure having a second semiconductor in which the germanium concentration exceeds the germanium concentration of the first semiconductor.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

Complementary field effect transistors (CFETs) may be utilized to increase the density of transistors in an integrated circuit. A CFET may include an N-type transistor and a P-type transistor stacked vertically. The gate electrodes of the N-type and P-type transistors may be electrically shorted together.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are cross-sectional views of an integrated circuit including a CFET at various stages of processing, in accordance with some embodiments.

FIGS. 2A and 2B are cross-sectional views of an integrated circuit at various stages of processing, in accordance with some embodiments.

FIGS. 3A-3J are cross-sectional views of an integrated circuit at various stages of processing, in accordance with some embodiments.

FIG. 4 is a flow diagram of a process for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least some embodiments. Thus, the appearances of the phrases “in one embodiment”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in this specification and the appended claims, the terms “fill,” “fills,” “filling” and “filled” include the meaning of partially fill and completely fill (or fills, filling, filled, etc.). For example, a conductive layer may be said to “fill” an opening, which may include that the conductive layer contacts adjacent walls of the opening, or that the conductive layer is present in the opening with one or more different material layers between the conductive layer and the adjacent walls.

As used in this specification and the appended claims, the terms “surround,” “surrounds,” “surrounding” and “surrounded” include the meaning of completely surround and partially surround (or surrounds, surrounding, surrounded, etc.). For example, a six-sided volume (e.g., a rectangular prism) being “surrounded” includes the meanings of being fully surrounded on all six sides by a material, or may be partially surrounded, such that one or more of the six sides is less than fully covered by the material and has at least a portion thereof exposed.

In many CFETs, SiGe is used as a source/drain (S/D). To avoid damage to the epitaxial layers during sheet formation, an SiB layer (formed in a channel adjacent to the epitaxial layer) and a lower Ge composition SiGe layer (L1) are grown prior to growing a high Ge layer (L2).

In embodiments of the disclosure, a silicon germanium layer can be replaced with a pure or high-concentration germanium layer for the source/drain. The replacement can occur following a source/drain epitaxy process(es) that grows upper source/drains, lower source/drains or both.

With pure Ge or high Ge % SiGe (e.g., 75%-100% Ge) as the source/drain, lattice constant can be increased, and the strain applied to the channel(s) is greatly increased, resulting in an increased drive current. With pure Ge or high Ge % SiGe (e.g., 75%-100% Ge) as the source/drain, source/drain contact resistance can be reduced, resulting in a current boost.

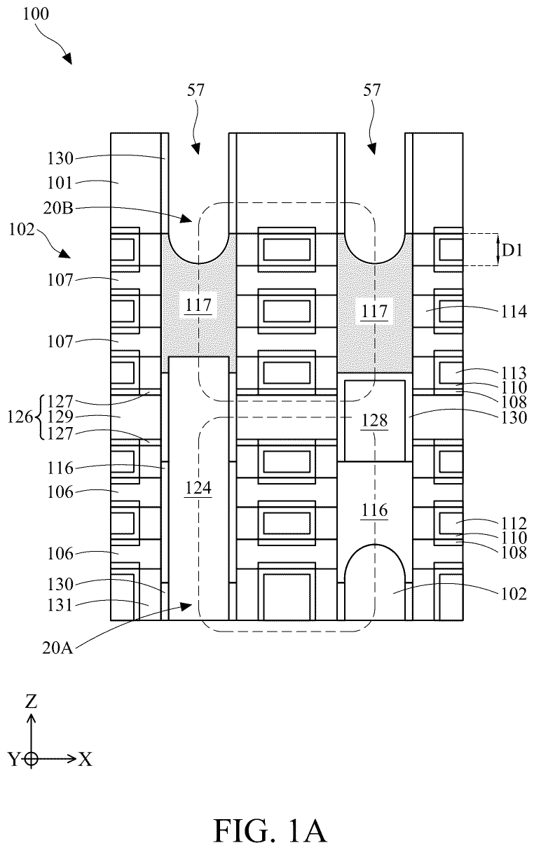

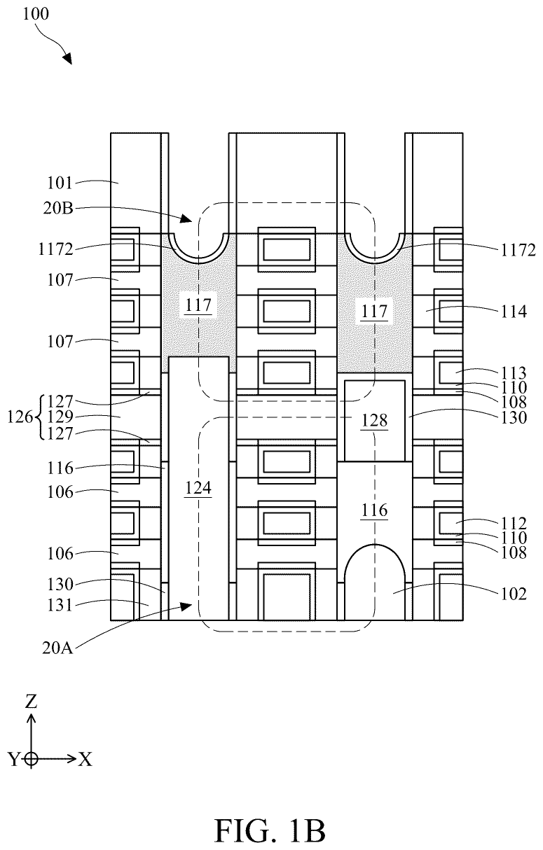

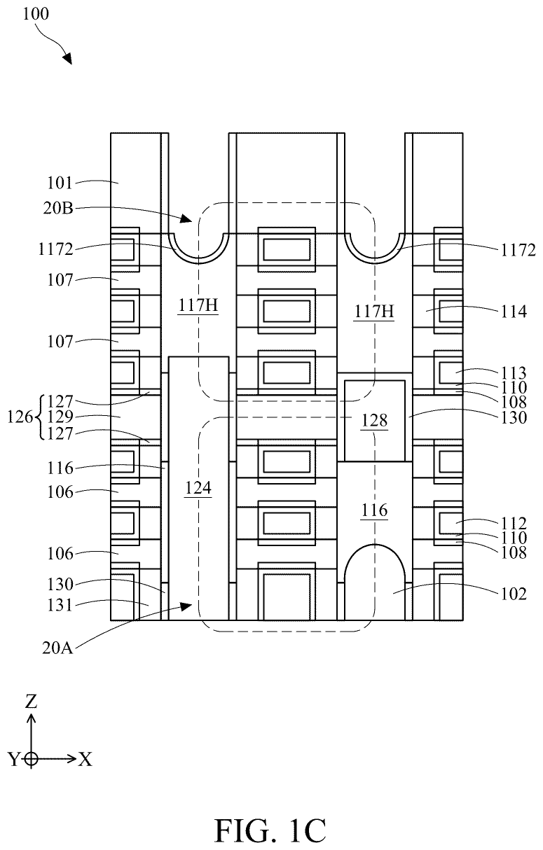

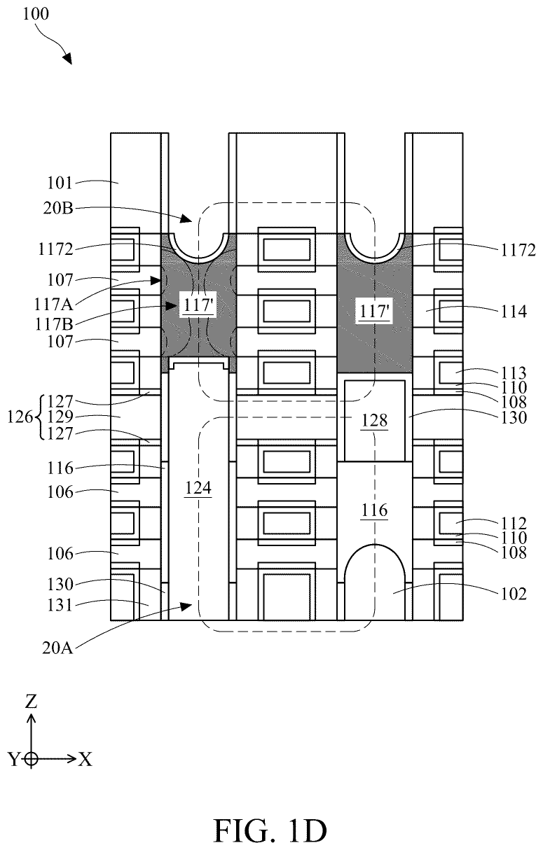

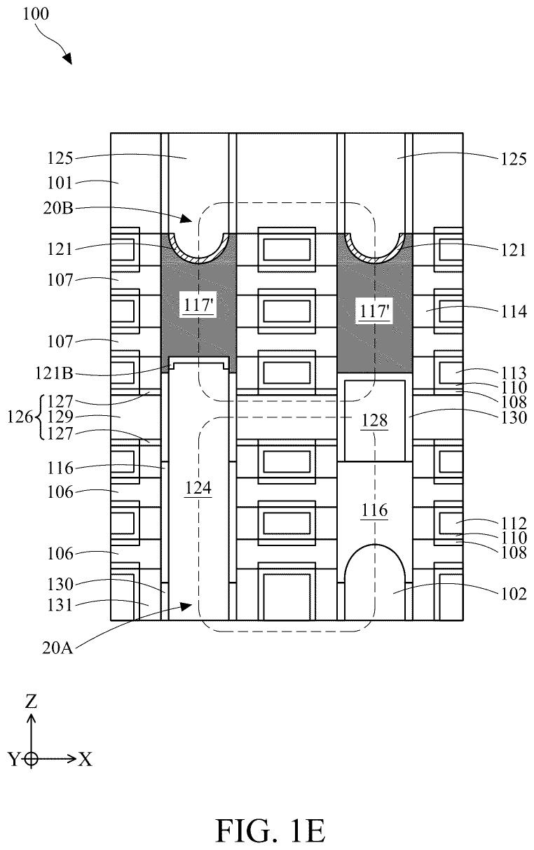

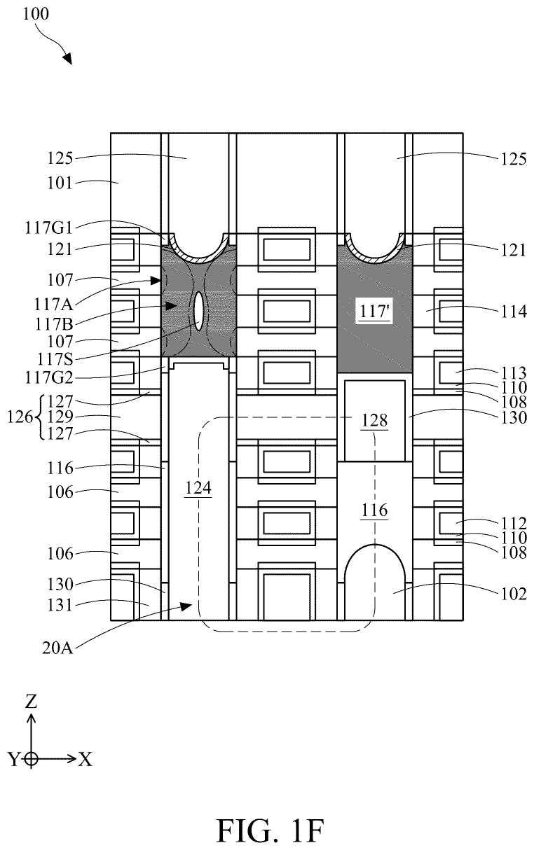

FIGS. 1A-1F are cross-sectional views of an integrated circuit 100 including a CFET at various stages of processing, in accordance with some embodiments. Some features may be omitted from view in the figures for clarity of illustration.

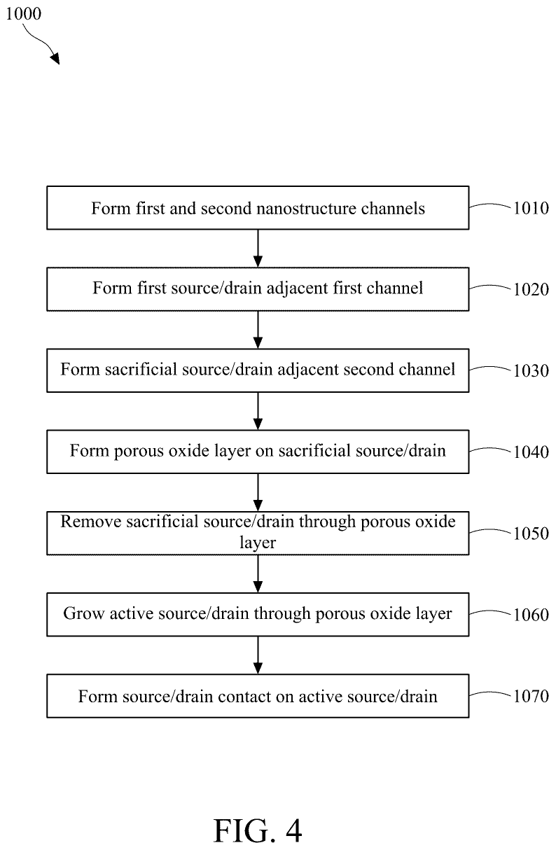

FIG. 4 depicts a flowchart of a method 1000 for forming an IC device or a portion thereof from a workpiece, according to one or more aspects of the present disclosure. Method 1000 is merely an example and not intended to limit the present disclosure to what is explicitly illustrated in method 1000. Additional acts can be provided before, during and after the method 1000 and some acts described can be replaced, eliminated, or moved around for additional embodiments of the method. For example, act 1020 may be eliminated or may be performed following act 1060. Not all acts are described herein in detail for reasons of simplicity. Method 1000 is described below in conjunction with fragmentary perspective and/or cross-sectional views of a workpiece, shown in FIGS. 1A-3H, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

The integrated circuit 100 includes a complimentary field effect transistor (CFET) 102. The CFET 102 includes a first transistor 20A of a first conductivity type and a second transistor 20B of a second conductivity type. The first transistor 20A is vertically stacked on the second transistor 20B. The CFET 102 utilizes an isolation structure 126 to separate the stacked channel regions of the first transistor 20A from the stacked channels of the second transistor 20B in order to improve electrical characteristics of the CFET 102. In other words, a hybrid nanostructure (e.g., hybrid sheet) including the stacked channel region of first transistor 20A, isolation structure 126, and the stacked channel region of second transistor 20B is formed.

The CFET transistor 20A may correspond to a gate all around transistor. The gate all around transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the gate all around structure. Furthermore, the gate all around CFET 102 may include a plurality of semiconductor nanostructures corresponding to channel regions of the CFET 102. The semiconductor nanostructures may include nanosheets, nanowires, or other types of nanostructures. The gate all around transistors may also be termed nanostructure transistors.

The view of FIG. 1A is an X-view of the integrated circuit 100 in which the X-axis is the horizontal axis, the Z-axis is the vertical axis, and the Y-axis extends into and out of the drawing sheet. As used herein, the term “X-view” corresponds to a cross-sectional view in which the X-axis is the horizontal dimension and the Z-axis is the vertical dimension. As used herein, the term “Y-view” corresponds to a cross-sectional view in which the Y-axis is the horizontal dimension and the Z-axis is the vertical dimension.

The integrated circuit 100 includes a substrate 101. The substrate 101 can include a semiconductor layer, a dielectric layer, or combinations of semiconductor layers and dielectric layers. Furthermore, conductive structures may be formed within the substrate 101 as backside conductive vias and interconnections, as will be described in more detail below. In some embodiments, the substrate 101 includes a single crystalline semiconductor layer on at least a surface portion. The substrate 101 may include a single crystalline semiconductor material such as, but not limited to Si, Ge, SiGe, GaAs, InSb, GaP, GaSb, InAlAs, InGaAs, GaSbP, GaAsSb and InP.

In some embodiments, the substrate 101 may include dielectric layers including one or more of can include silicon oxide, silicon nitride, silicon oxynitride, silicon carbonitride, silicon oxycarbonitride, fluorine-doped silicate glass (FSG), a low-K dielectric material or other dielectric materials. In some embodiments, the substrate 101 may include shallow trench isolation regions formed in a semiconductor layer. Various configurations of a substrate 101 can be utilized without departing from the scope of the present disclosure. In some embodiments, the substrate 101 is not present, for example, when removed prior to forming a backside interconnect structure.

The transistor 20B is formed above the substrate 101. In the view of FIG. 1A, the integrated circuit 100 is flipped corresponding to processing being performed via a back side of the integrated circuit 100. The transistor 20A is positioned above the transistor 20B. In some embodiments, the transistor 20A is an N-type transistor and the transistor 20B is a P-type transistor. In some embodiments, the transistor 20A may be a P-type transistor and the transistor 20B may be an N-type transistor.

The transistor 20A includes a plurality of semiconductor nanostructures 106. The semiconductor nanostructures 106 are stacked in the vertical direction or Z-direction. In the example of FIG. 1A, two stacked semiconductor nanostructures 106 are depicted. However, in practice, there may be three or more stacked semiconductor nanostructures 106 without departing from the scope of the present disclosure. Furthermore, in some embodiments there may be only a single semiconductor nanostructure 106 and a single semiconductor nanostructure 107. The semiconductor nanostructures 106 correspond to channel regions of the transistor 20A. The semiconductor nanostructures 106 may be nanosheets, nanowires, or other types of nanostructures.

The transistor 20B includes a plurality of semiconductor nanostructures 107. The semiconductor nanostructures 107 are stacked in the vertical direction or Z-direction. In the example of FIG. 1A, there are three stacked semiconductor nanostructures 107. However, in practice, there may be only two stacked nanostructures 107 or there may be more than three stacked nanostructures 107 without departing from the scope of the present disclosure. The semiconductor nanostructures 107 correspond to channel regions of the transistor 20B. The semiconductor nanostructures 107 may be nanosheets, nanowires, or other types of nanostructures. The number of semiconductor nanostructures 107 may be the same as the number of semiconductor nanostructures 106 or may be different than the number of semiconductor nanostructures 106.

The semiconductor nanostructures 106 and 107 may include Si, SiGe, Ge, SiGeSn, GeSn or other semiconductor materials. In a non-limiting example described herein, the semiconductor nanostructures 106 are silicon. The vertical thickness of the semiconductor nanostructures 106 can be between 2 nm and 5 nm. The semiconductor nanostructures 106 may be separated from each other in the vertical direction by 4 nm to 10 nm. Other thicknesses and materials can be utilized for the semiconductor nanostructures 106 without departing from the scope of the present disclosure. The semiconductor nanostructures 107 may have a same material and dimensions as the semiconductor nanostructures 106 or a different semiconductor material from the semiconductor nanostructures 106.

The transistors 20A and 20B include a gate dielectric. The gate dielectric includes an interfacial gate dielectric layer 108 and a high-K gate dielectric layer 110. The interfacial gate dielectric layer 108 is a low-K gate dielectric layer. For example, the interfacial gate dielectric layer 108 may be a thin oxide layer of the underlying material of the semiconductor nanostructures 106 and 107. The interfacial gate dielectric layer 108 is in contact with the semiconductor nanostructures 106 and 107. The high-K gate dielectric layer 110 is in contact with the low-K gate dielectric layer 108. The interfacial gate dielectric layer 108 is positioned between the semiconductor nanostructures 106 and the high-K gate dielectric layer 110 and between the semiconductor nanostructures 107 and the high-K gate dielectric layer 110.

The interfacial gate dielectric layer 108 can include a dielectric material such as silicon oxide, silicon nitride, or other suitable dielectric materials. The interfacial dielectric layer 108 can include a comparatively low-K dielectric with respect to high-K dielectric such as hafnium oxide or other high-K dielectric materials that may be used in gate dielectrics of transistors. The interfacial dielectric layer 108 can include a native oxide layer that grows on surfaces of the semiconductor nanostructures 106 and 107. The interfacial dielectric layer 108 may have a thickness between 0.4 nm and 2 nm. Other materials, configurations, and thicknesses can be utilized for the interfacial dielectric layer 108 without departing from the scope of the present disclosure.

The high-K gate dielectric layer includes one or more layers of a dielectric material, such as HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof. The thickness of the high-k dielectric is in a range from about 1 nm to about 3 nm. Other thicknesses, deposition processes, and materials can be utilized for the high-K gate dielectric layer without departing from the scope of the present disclosure. The high-K gate dielectric layer may include a first layer that includes HfO₂ with dipole doping including La and Mg, and a second layer including a higher-K ZrO layer with crystallization.

The transistor 20A includes a gate metal 112. The gate metal 112 surrounds the semiconductor nanostructures 106. The gate metal 112 is in contact with the high-K gate dielectric layer 110. The gate metal 112 corresponds to a gate electrode of the transistor 20A. In an example in which the transistor 20A is an N-type transistor, the gate metal 112 can include a material that results in a beneficial work function with the semiconductor nanostructures 106. In one example, the gate metal 112 includes titanium aluminum, titanium, aluminum, tungsten, ruthenium, molybdenum, copper, gold, or other conductive materials. In some embodiments, the gate metal 112 surrounds the semiconductor nanostructures 106 on four sides, e.g., top, bottom, left and right sides. In some embodiments, such as in a forksheet transistor, the gate metal 112 may surround the semiconductor nanostructures 106 on three sides, with the gate metal 112 being substantially not present on the fourth side. For example, the gate metal 112 may be present on outer edges of the fourth side, and may occupy less than about 5% of area of the fourth side.

FIG. 1A illustrates a single gate metal 112. However, in practice, the gate electrode from the transistor 20A can include multiple metal layers. For example, the gate metal 112 can include one or more liner layers or adhesive layers such as tantalum, tantalum nitride, titanium nitride, or other materials. The gate metal 112 can include a gate fill material that fills the remaining volume between the semiconductor nanostructures 106 after the one or more liner layers have been deposited. Various materials, combinations of materials, and configurations may be utilized for the gate metal 112 without departing from the scope of the present disclosure.

The transistor 20B includes a gate metal 113. The gate metal 113 surrounds the semiconductor nanostructures 107. The gate metal 113 is in contact with the high-K gate dielectric layer 110. The gate metal 113 corresponds to a gate electrode of the transistor 20B. In an example in which the transistor 20B is a P-type transistor, the gate metal 113 can include a material that results in a desired work function with the semiconductor nanostructures 107. In one example, the gate metal 113 includes titanium nitride, titanium, aluminum, tungsten, ruthenium, molybdenum, copper, gold, or other conductive materials. In some embodiments, the gate metal 113 is or includes one or more different materials than the gate metal 112.

FIG. 1A illustrates a single gate metal 113. However, in practice, the gate electrode from the transistor 20B can include multiple metal layers that wrap around the semiconductor nanostructures 107. For example, the gate metal 112 can include one or more liner layers or adhesive layers such as tantalum, tantalum nitride, titanium nitride, or other materials. The gate metal 113 can include a gate fill material that fills the remaining volume between the semiconductor nanostructures 107 after the one or more liner layers have been deposited. Various materials, combinations of materials, and configurations may be utilized for the gate metal 113 without departing from the scope of the present disclosure.

The transistor 20A includes source/drain regions 116. The source/drain regions 116 are in contact with each of the semiconductor nanostructures 106. Each semiconductor nanostructure 106 extends in the X-direction between the source/drain regions 116. The source/drain regions 116 include a semiconductor material. The transistor 20B includes sacrificial source/drain regions 117. The sacrificial source/drain regions 117 are in contact with each of the semiconductor nanostructures 107. Each semiconductor nanostructure 107 extends in the X-direction between the sacrificial source/drain regions 117. The sacrificial source/drain regions 117 include a semiconductor material.

In an example in which the transistor 20A is an N-type transistor and the transistor 20B is a P-type transistor, the source/drain regions 116 can be doped with N-type dopant species. The N-type dopant species can include P, As, or other N-type dopant species. The sacrificial source/drain regions 117 can be doped with P-type dopant species in the case of a P-type transistor. The P-type dopant species can include B or other P-type dopant species. The doping can be performed in-situ during an epitaxial growth process of the source/drain regions 117. The source/drain regions 116 and 117 can include other materials and structures without departing from the scope of the present disclosure. Generally, due to the sacrificial source/drain regions 117 being sacrificial, in many embodiments, the sacrificial source/drain regions 117 are not doped with dopant species, which is beneficial to reduce processing steps. In some embodiments, when beneficial to increase etch selectivity of the sacrificial source/drain regions 117 relative to structures and/or elements adjacent thereto, the sacrificial source/drain regions 117 may be doped with one or more appropriate dopants.

As used herein, the term “source/drain region” may refer to a source region or a drain region individually or collectively dependent upon the context. Accordingly, one of the source/drain regions 116 may be a source region while the other source/drain region 116 is a drain region, or vice versa. Furthermore, in some cases, one or both of the source/drain regions 116 may be shared with one or more laterally adjacent transistors.

The transistors 20A and 20B each include inner spacers 114. The inner spacers 114 can include silicon oxide, silicon nitride, silicon oxynitride, silicon carbonitride, silicon oxycarbonitride, fluorine-doped silicate glass (FSG), a low-K dielectric material or other dielectric materials without departing from the scope of the present disclosure. In one example, the inner spacers 114 include silicon oxycarbonitride.

The inner spacers 114 of the transistor 20A physically separate the gate metal 112 from the source/drain regions 116. This prevents short circuits between the gate metal 112 and the source/drain regions 116. The inner spacers 114 of the transistor 20B physically separate the gate metal 113 from the sacrificial source/drain regions 117. This prevents short circuits between the gate metal 113 and replacement or “active” source/drain regions that are formed in later operations.

The transistor 20A may include source/drain contacts 124. Each source/drain contact 124 is positioned over and is electrically connected to or in contact with a respective source/drain region 116 and optionally with a sacrificial source/drain region 117. Electrical signals may be applied to the source/drain regions 116 via the source/drain contacts. The source/drain contacts 124 may include silicide (not separately depicted for simplicity of illustration). The silicide is formed at the top of the source/drain regions 116. The silicide can include titanium silicide, aluminum silicide, nickel silicide, tungsten silicide, or other suitable silicides. As depicted in FIG. 1A, the source/drain contact 124 may extend fully through one of the source/drain regions 116 and land on a sacrificial source/drain region 117 thereabove. In some embodiments, one or more of the source/drain regions 116 or sacrificial source/drain regions 117 does not have a source/drain contact 124 connected thereto or in contact therewith. In some embodiments, both of the source/drain contacts 124 extend fully through the respective source/drain region 116 to land on the respective sacrificial source/drain region 117.

The source/drain contacts 124 may be or include a conductive layer, a barrier layer, or both, which are positioned on the silicide. The barrier layer can include titanium nitride, tantalum nitride, titanium, tantalum, or other suitable conductive materials. The conductive layer can include a conductive material such as tungsten, cobalt, ruthenium, titanium, aluminum, tantalum, or other suitable conductive materials. Other materials and configurations can be utilized for the source/drain contacts 124 without departing from the scope of the present disclosure.

The transistor 20A includes sidewall spacers 131. The sidewall spacers 131 are positioned adjacent to the uppermost portion of the gate metal 112 and electrically isolate the gate metal 112 from the source/drain contacts 124. The sidewall spacers 131 may include one or more of silicon oxide, silicon nitride, silicon oxynitride, silicon carbonitride, silicon oxycarbonitride, fluorine-doped silicate glass (FSG), a low-K dielectric material or other dielectric materials. Other thicknesses and materials can be utilized for the sidewall spacers 131 without departing from the scope of the present disclosure.

The transistor 20A may include a gate cap metal (not separately depicted for simplicity of illustration) positioned on an uppermost portion of the gate metal 112. In some embodiments, the gate cap metal includes tungsten, fluorine free tungsten, or other suitable conductive materials. The gate cap metal may have a height between 1 nm and 10 nm. Other configurations, materials, and thicknesses can be utilized for the gate cap metal without departing from the scope of the present disclosure.

Operation of the CFET 102 can be described generally with reference to FIG. 1A, however it should be noted that the source/drain regions 117 are replaced in a later operation with second source/drain regions 117′ that are pure Ge or high-Ge-concentration source/drain regions 117′ (see FIG. 1D, for example). The CFET 102 can be operated by applying voltages to the source/drain regions 116/117′ and the gate metals 112/113. The voltages can be applied to the source/drain regions 116/117′ via the source/drain contacts 124/125. The voltages can be applied to the gate metals 112/113 via a gate contact not shown in FIG. 1A. Though not apparent in the view of FIG. 1A, the gate metal 112 and the gate metal 113 can be shorted together. Accordingly, the gate metal 112 and the gate metal 113 can jointly correspond to a gate electrode of the CFET 102. The voltage applied to the gate metals 112/113 may turn on the transistor 20A and turn off the transistor 20B or may turn on the transistor 20B and turn off the transistor 20A. While the gate metals 112/113 are shorted together, the source/drain regions 116 are not shorted together with the source/drain regions 117′. Depending on a particular electrical circuit configuration, the flow of current can be selectively enabled or prohibited through the source/drain regions 116 and 117′ individually.

As described previously, it may be beneficial to obtain desired work functions for the transistors 20A and 20B by utilizing different materials for the gate metals 112 and 113. One possible way of forming the gate metals 112/113 is to first deposit the gate metal 113 around all of the semiconductor nanostructures 106 and 107 and then to perform a timed etch to remove the gate metal 113 from around the semiconductor nanostructures 106. This is followed by depositing the gate metal 112 around the semiconductor nanostructures 106 after the timed etch of the gate metal 113. However, one drawback of this process is that in some cases the gate metal 113 may not be entirely removed directly below the lowest semiconductor nanostructure 106. This can interfere with the work function of the transistor 20A, thereby affecting the threshold voltage of the transistor 20A in an undesired manner.

The CFET 102 avoids or reduces the possibility of work function interference by utilizing an isolation structure 126 between the semiconductor nanostructures 106 and the semiconductor nanostructures 107. More particularly, the isolation structure 126 is positioned directly between the lowest semiconductor nanostructure 106 and the highest semiconductor nanostructure 107. The isolation structure 126 may include upper and lower semiconductor layers 127 and a dielectric layer 129 between the upper and lower semiconductor layers 127. Various structures and compositions can be utilized for the isolation structure 126 without departing from the scope of the present disclosure.

The dielectric layer 129 may include silicon oxide, silicon nitride, silicon oxynitride, silicon carbonitride, silicon oxycarbonitride, fluorine-doped silicate glass (FSG), a low-K dielectric material or other dielectric materials. The dielectric layer 129 may have a length in the X direction between 15 nm and 30 nm. A length in this range may be sufficient to match or exceed the length of the semiconductor nanostructures 106 and 107 in the X direction. However, depending on the length of the semiconductor nanostructures 106 and 107, a greater or lower length of the dielectric layer 129 may be selected. The dielectric layer 129 may have a height in the Z direction between 5 nm and 25 nm. These dimensions may be sufficient to ensure that there is no possibility of work function interference from the gate metal 113 with the semiconductor nanostructures 106. Furthermore, these dimensions may provide reduced gate to drain capacitance. Other materials, dimensions, and configurations can be utilized for the dielectric layer 129 without departing from the scope of the present disclosure. The dielectric layer 129 may be termed a dielectric nanostructure. The dielectric nanostructure can include a dielectric nanosheet, the dielectric nanowires, or another type of dielectric nanostructure.

Each semiconductor layer 127 may have a vertical thickness between 1 nm and 5 nm. The semiconductor layers 127 may include silicon or another suitable semiconductor material. Other materials and dimensions may be utilized for the semiconductor layers 127 without departing from the scope of the present disclosure.

Although FIG. 1A illustrates a single dielectric layer 129, in practice, the dielectric layer 129 may include multiple layers of different dielectric material between the semiconductor layers 127. For example, a first dielectric layer of silicon oxide may be positioned in contact with each of the semiconductor layers 127. A second dielectric layer of silicon nitride may be positioned between upper and lower portions of the first dielectric layer. Various configurations for a dielectric barrier between the top semiconductor nanostructure 107 and the bottom semiconductor nanostructure 106 may be utilized without departing from the scope of the present disclosure.

Formation of the device 100 depicted in FIG. 1A can include forming the nanostructure channels 106, 107, which corresponds to act 1010 of FIG. 4. In some embodiments, formation of the device 100 further includes forming the source/drains 116 adjacent the nanostructure channels 106, which corresponds to act 1020 of FIG. 4. Formation of the device 100 includes forming the sacrificial source/drains 117 adjacent the nanostructure channels 107.

In FIGS. 1A-1F, the sacrificial source/drains 117 are replaced with replacement source/drains 117′ that are able to increase strain in the semiconductor nanostructures or channels 107. Increasing the strain can improve drive current that can be conducted through the channels 107. In some embodiments in which the replacement source/drains 117′ include pure or high-concentration germanium instead of SiGe, source/drain contact resistance can be reduced, which can also increase current conduction. The replacement source/drains 117′ may be referred to as second source/drains 117′ or active source/drains 117′ throughout the description.

In FIG. 1A, first openings 57 are formed that expose upper surfaces of the sacrificial source/drains 117. The first openings 57 may be formed, for example, through an interlayer dielectric that is partially or completely removed in the profile view of FIG. 1A. As depicted, the interlayer dielectric is completely removed when forming the first openings 57. Formation of the first openings 57 can be via a suitable etching operation, such as a wet etch, dry etch or atomic layer etch (ALE) that is selective to material of the interlayer dielectric without substantially attacking material of the dielectric layer 130.

In some embodiments, following formation of the first openings 57, the upper surfaces of the sacrificial source/drains 117 are concave in profile. In some embodiments, the upper surfaces are flat in the profile. In some embodiments, depth DI between the uppermost level of the upper surface of the sacrificial source/drains 117 and a lowermost level of the upper surface can be in a range of about 0 nm to about 15 nm. Namely, the depth DI can measure depth of concavity of the sacrificial source/drains 117 after forming the first openings 57. The concavity can be due to overetching into material of the sacrificial source/drains 117 when removing the interlayer dielectric thereover.

In FIG. 1B, an oxidation process is performed that forms a porous oxide layer 1172 over the sacrificial source/drain region 117 on exposed upper surfaces thereof, corresponding to act 1040 of FIG. 4. Thickness of the porous oxide layer 1172 may be in a range of about 0.8 nm to about 2 nm, such as about 1 nm. Formation of the porous oxide layer 1172 may include thermal oxidation, where the SiGe sacrificial source/drain region 117 is exposed to oxygen or water vapor at high temperatures. The thermal oxidation process can cause the silicon in the SiGe alloy to react with oxygen, forming silicon dioxide (SiO₂). Because germanium oxidizes differently than silicon, a less stable germanium oxide (GeOx) that can volatilize at the oxidation temperatures may be formed, affecting uniformity and quality of the porous oxide layer 1172. Namely, pores may be present in the porous oxide layer 1172 that extend entirely through the porous oxide layer 1172 such that the sacrificial source/drain region 117 is exposed at least partially through the porous oxide layer 1172.

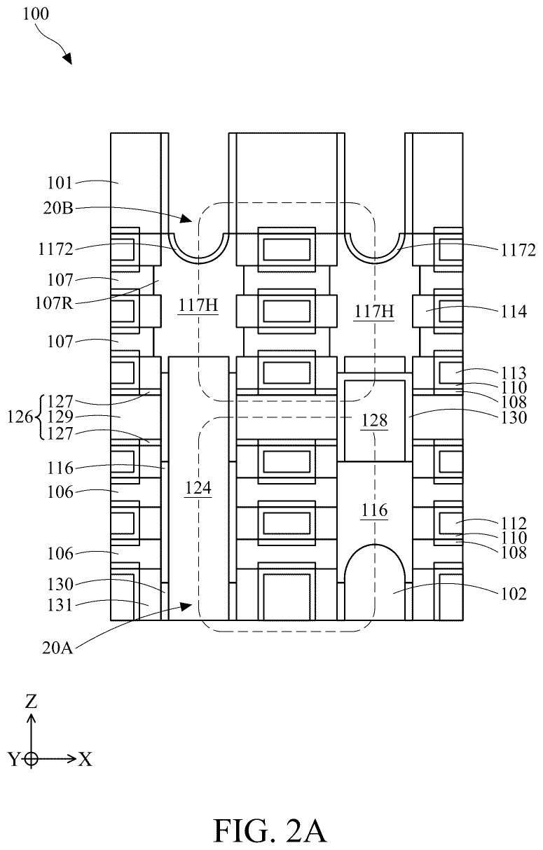

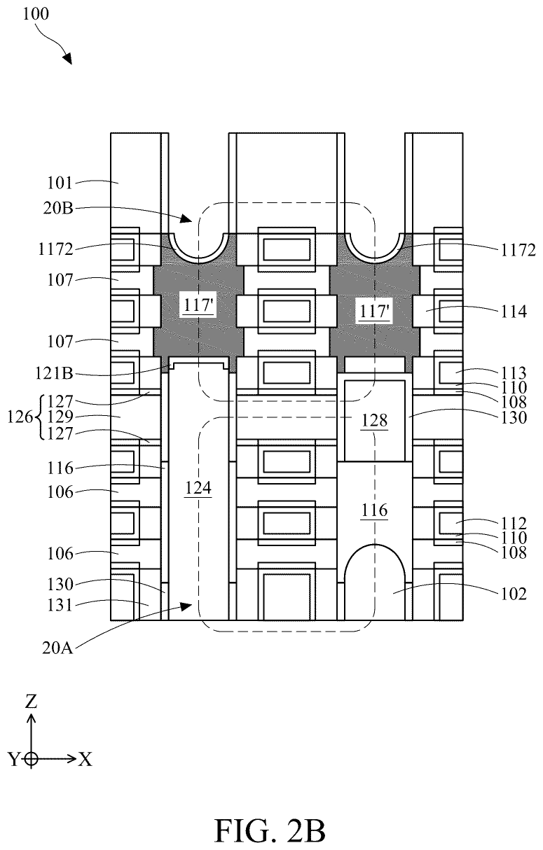

In FIG. 1C, the sacrificial source/drain regions 117 are removed to form openings 117H, corresponding to act 1050 of FIG. 4. The sacrificial source/drain regions 117 may be removed via a suitable etching operation, which may include a chlorine-based etchant, a fluorine-based etchant, or the like. The etchant, which can be a gas, may penetrate through the porous oxide layer 1172 and etch the SiGe of the sacrificial source/drain regions 117, resulting in the sacrificial source/drain regions 117 being removed and the openings 117H being formed. The openings 117H may inherit shape of the sacrificial source/drain regions 117, as depicted in FIG. 1C. In some embodiments, as described with reference to FIGS. 2A and 2B, some overetching may occur that removes end portions of the nanostructures 107.

In FIG. 1D, following formation of the openings 117H, replacement or “active” source/drain regions 117′ are formed in the openings 117H through the porous oxide layer 1172, corresponding to act 1060 of FIG. 4. The replacement source/drain regions 117′ can be formed by a suitable epitaxial growth operation that grows material of the replacement source/drain regions 117′ in the openings 117H. The replacement source/drain regions 117′ can be or include one or more semiconductor materials, which can include SiGe, Ge, GeSn, SiGeSn. In the replacement source/drain regions 117′, concentration of germanium (“germanium concentration”) can be in a range of about 75% to 100% (i.e., pure Ge). Epitaxial growth of Ge or SiGe in the source/drain openings can be performed via chemical vapor deposition (CVD), molecular beam epitaxy (MBE), or the like. In CVD, gases containing the selected elements (e.g., germane for Ge, silane for Si, and optionally diborane, phosphine, TMGa, TEGa, AsH₃ or TBA for doping) are introduced into a reaction chamber. The device 100 can be heated to a high temperature, such that the gases react or decompose to form the epitaxial layer. CVD can be beneficial for good uniformity and control over layer composition. MBE can provide benefits of increased precision where the elements are evaporated in a high-vacuum environment and then condense on the heated device 100. MBE can provide excellent control over the thickness and composition of the epitaxial layer of the replacement source/drain regions 117′ at the atomic level, beneficial for nanoscale devices.

In CVD and MBE, the porous oxide layer 1172 is permeable to the gases (e.g., germane, silane, diborane, phosphine, and the like), such that the gases may react or decompose at the nanostructures 107 in the openings 117H. Namely, exposed side surfaces of end portions of the nanostructures 107 can have the semiconductor material grown thereon. As depicted by dashed lines in FIG. 1D, during the growth process, the growth may initially occur to form first regions 117A on the end portions of the nanostructures 107. Then, as the process continues over time, the growth may continue such that the first regions 117A enlarge and eventually merge to form second regions 117B. Finally, growth continues until the second regions 117B on either side of the opening 117H merge with each other and are in contact at least with the nanostructures 107, the inner spacers 114, the source/drain contact 124 when present, the dielectric layer 130 and the porous oxide layer 1172. In some embodiments, one or more air gaps may be formed at corner regions of the replacement source/drain region 117′ due to growth profile of the semiconductor material in the openings 117H. Formation of air gaps is described in greater detail with reference to FIG. 1F.

In some embodiments, the dopants are introduced into the replacement source/drain regions 117′ in situ, as described above. In some embodiments, the dopants include B, Ga, P, As or the like. In the growth process, diborane, phosphine, trimethylgallium, triethylgallium, arsine, tertiarybutylarsine or the like may be flowed in gaseous state to dope the replacement source/drain regions 117′ in situ. In some embodiments, the replacement source/drain regions 117′ may be doped in a subsequent operation, for example, by implantation of one or more of B, Ga, P, As or the like.

In FIG. 1E, following formation of the replacement source/drain regions 117′, source/drain contacts 125 can be formed on the replacement source/drain regions 117′, corresponding to act 1070 of FIG. 4. Each source/drain contact 125 is positioned on and is electrically connected to a respective replacement source/drain region 117′. Electrical signals may be applied to the replacement source/drain regions 117′ via the source/drain contacts 125.

The source/drain contacts 125 may be or include one or more conductive layers positioned on the silicide 121. For example, a barrier or liner layer can include titanium nitride, tantalum nitride, titanium, tantalum, or other suitable conductive materials. A conductive fill layer can be on the barrier or liner layer and can include a conductive material such as tungsten, cobalt, ruthenium, titanium, aluminum, tantalum, or other suitable conductive materials. Other materials and configurations can be utilized for the source/drain contacts 125 without departing from the scope of the present disclosure.

The source/drain contacts 125 may include silicide 121. The silicide 121 is formed at the interface of the replacement source/drain regions 117′ with the source/drain contacts 125. The silicide 121 may reduce the source/drain contact resistance. In some embodiments, the silicide 121 is or includes TiSi, CrSi, TaSi, MoSi, ZrSi, HfSi, ScSi, YSi, HoSi, TbSi, GdSi, LuSi, DySi, ErSi, YbSi, or the like. In some embodiments, the silicide 121 is or includes NiSi, CoSi, MnSi, WSi, FeSi, RhSi, PdSi, RuSi, PtSi, IrSi, OsSi, or the like. The silicide 121 can be an alloy between the source/drain contact 125 and the replacement source/drain region 117′ that can be a mixture of one or more of Ti, Ru, Mo, Ni, Co, W or the like and one or more of Ge, SiGe, SiGeSn, GeSn or the like. The silicide 121 may have thickness in a range of about 1 nm to about 10 nm. Thickness lower than about 1 nm may lead to an insufficient reduction in contact resistance. Thickness above about 10 nm may cause electrical shorting with the nanostructures 107. In some embodiments, the silicide 121 is present below, and in contact with, the dielectric layer 130. As depicted in FIG. 1E, in some embodiments, backside silicide 121B is present at the interface between the second source/drain 117′ and the source/drain contact 124. The backside silicide 121B may be similar in most respects to the silicide 121, but may be formed during growth of the semiconductor material of the second source/drain 117′ instead of during formation of the source/drain contacts 125.

FIG. 1F depicts optional air gaps 117G1, 117G2 that may be present at corner regions of the second source/drain region 117′. First air gaps 117G1 may be present adjacent the silicide 121 and inner spacer 114 that is immediately adjacent the substrate 101. Second air gaps 117G2 may be present adjacent the source/drain contact 124 and the inner spacer 114 immediately adjacent the isolation structure 126. As described previously with reference to FIG. 1D, during the growth process of the second source/drain region 117′, the growth may initially occur on the end portions of the nanostructures 107 to form first regions 117A depicted by first dashed lines. Then, as the process continues over time, the growth may continue such that the first regions 117A enlarge and eventually merge to form second regions 117B. Finally, growth continues until the second regions 117B on either side of the opening 117H merge with each other and are in contact at least with the nanostructures 107, the inner spacers 114, the source/drain contact 124 when present, the dielectric layer 130 and the porous oxide layer 1172.

In some embodiments, growth of the second source/drain region 117′ may terminate prior to the semiconductor material thereof reaching the uppermost portion of the inner spacer 114 immediately adjacent to the substrate 101, resulting in formation of the air gaps 117G1. Height of the air gaps 117G1 in the Z-axis direction may be in a range of 0 nm to about 5 nm.

Formation of the air gaps 117G2 may be due to merging or overhang of the semiconductor material occurring prior to filling the small space that is laterally between the source/drain contact 124 and the inner spacer 114 immediately adjacent to the isolation structure 126, resulting in the air gaps 117G2. Height of the air gaps 117G2 in the Z-axis direction may be in a range of 0 nm to about 5 nm.

In some embodiments, the air gaps 117G1 are present while the air gaps 117G2 are not present. In some embodiments, the air gaps 117G2 are present while the air gaps 117G1 are not present. In some embodiments, neither or both of the air gaps 117G1, 117G2 are present.

In some embodiments, a seam 117S may be present due to merging of the semiconductor material of the second source/drain region 117′. The seam 117S may be an air gap as shown or may be a visible interface that extends roughly along the vertical direction, such as the Z-axis direction.

As depicted in FIG. 1F, when the underside of the replacement source/drain 117′ is immediately adjacent to the interlayer or interlevel dielectric 128 and the dielectric layer 130, e.g., when no source/drain contact 124 extends through the interlevel dielectric 128 to make electrical connection with the replacement source/drain 117′, growth of the replacement source/drain 117′ may be different than in regions of the device 100 in which the source/drain contact 124 does extend through the interlevel dielectric 128. For example, the second air gaps 117G2, the seam 117S, or both may not be present in such regions, as depicted.

FIGS. 2A and 2B are cross-sectional views of an integrated circuit 100 at various stages of processing, in accordance with some embodiments.

FIG. 2A depicts an embodiment in which, following formation of the porous oxide layer 1172, the openings 117H are formed by removing the sacrificial source/drains 117 through the porous oxide layer 1172. As described with reference to FIG. 1C, etchant gases can permeate through the pores of the porous oxide layer 1172 to react with and remove the semiconductor material (e.g., SiGe) of the sacrificial source/drains 117′. In some embodiments, as depicted in FIG. 2A, during removal of the sacrificial source/drains 117′, some overetching may occur in which end portions of the nanostructures 107 are removed or recessed. Removal of the end portions of the nanostructures 107 may result in recesses 107R, such that side surfaces of the nanostructures 107 are recessed back from side surfaces of the inner spacers 114. In some embodiments, length of the recesses 107R, such as distance in the X-axis direction between the side surface of the inner spacers 114 and the nanostructure 107 therebetween, can be in a range of about 0.5 nm to about 3 nm. Due to the recessing of the nanostructures 107 during replacement of the sacrificial source/drains 117 with the active source/drains 117′, the nanostructures 107 may have width that is shorter in the X-axis direction than that of the nanostructures 106. The difference in widths between the nanostructures 107 and the nanostructures 106 may be in a range of about 1 nm to about 4 nm. Namely, width of the nanostructures 106 not associated with replacement of the source/drain 116 can exceed width of the nanostructures 107 associated with replacement of the source/drain 117 by about 1 nm to about 4 nm.

In FIG. 2B, following formation of the openings 117H that have the recesses 117R, the second source/drain 117′ is formed in the openings 117H through the porous oxide layer 1172. Formation of the second source/drain 117′ in FIG. 2B is similar in most respects to that described with reference to FIG. 1D other than that the second source/drain 117′ in FIG. 2B is formed in the recesses 117R and has portions that extend into the space of the recesses 117R that is vertically between the inner spacers 114. As discussed with reference to FIG. 2A, the nanostructures 106 may have width that exceeds width of the nanostructures 107 due to the partial etching of the end portions of the nanostructures 107. Similarly, due to the decreased width of the nanostructures 107 relative to the nanostructures 106, the second source/drain 117′ may have width that exceeds width of the source/drain 116. For example, the width of the second source/drain 117′ may exceed the width of the source/drain 116 by about 1 nm to about 4 nm.

In the description made with reference to FIGS. 1D and 2B, the second source/drain 117′ is formed by flowing precursor gases of the semiconductor material thereof and optionally of dopants thereof through pores in the porous oxide layer 1172. In some embodiments, the porous oxide layer 1172 may be removed prior to formation of the second sourced/drain 117′. For example, a suitable etch operation, such as a dry etch or vapor phase etch, may be performed to remove material of the porous oxide layer 1172, then a cleaning operation may be performed to remove any residue of the porous oxide layer 1172 prior to formation of the second source/drain 117′.

In some embodiments, instead of filling the recesses 117R with high-Ge-concentration semiconductor material, the recesses 117R may be filled with another semiconductor material, such as SiB, prior to growing the high-Ge-concentration semiconductor material.

In the embodiments described with reference to FIGS. 1A to 2B, the source/drains 116 and the sacrificial source/drains 117 are formed prior to replacing the sacrificial source/drains 117 with the active source/drains 117′. In some embodiments, the sacrificial source/drains 117 are formed prior to the source/drains 116. As such, replacement of the sacrificial source/drains 117 with the active source/drains 117′ can occur prior to formation of the source/drains 116.

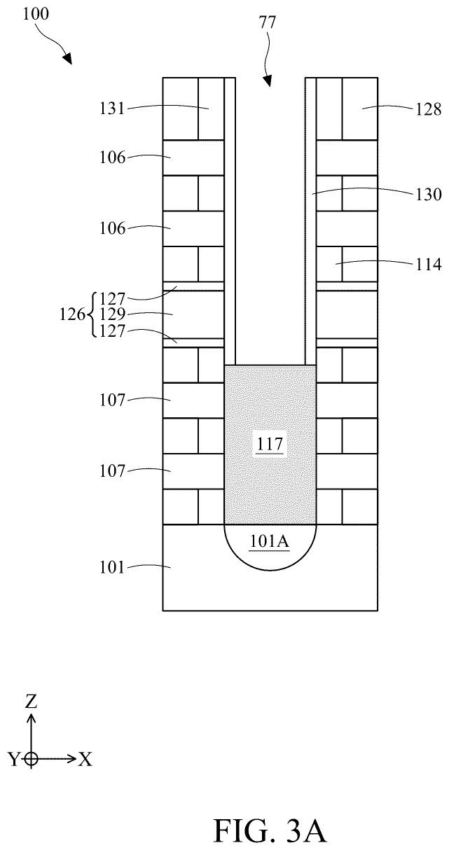

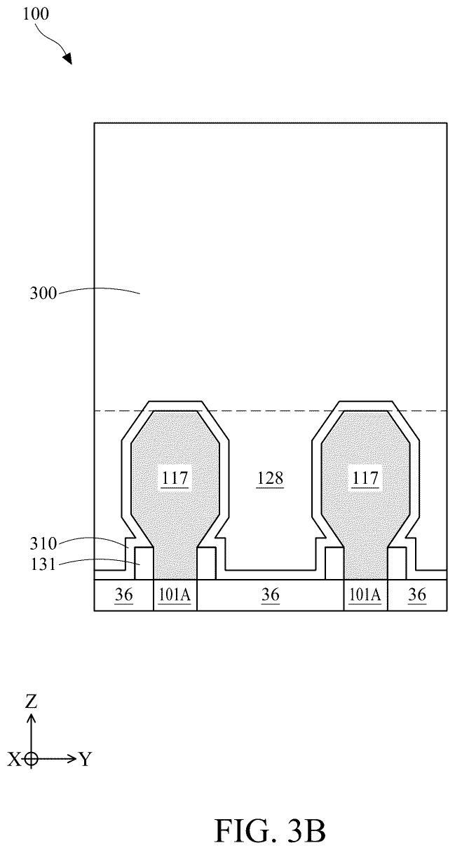

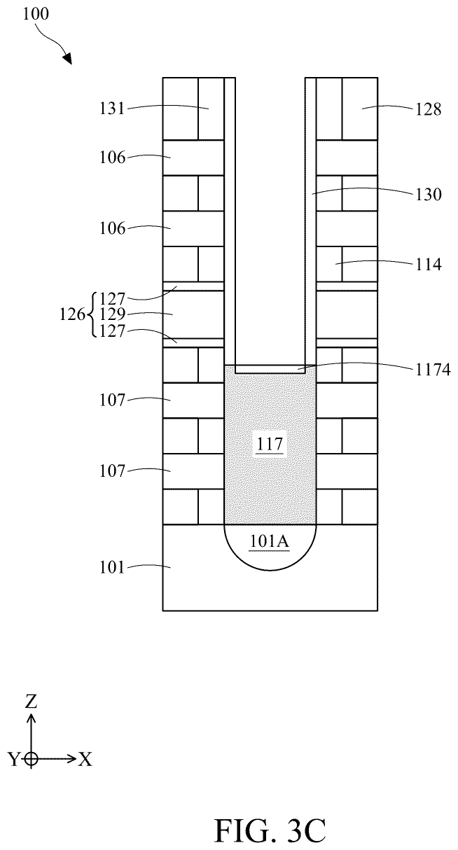

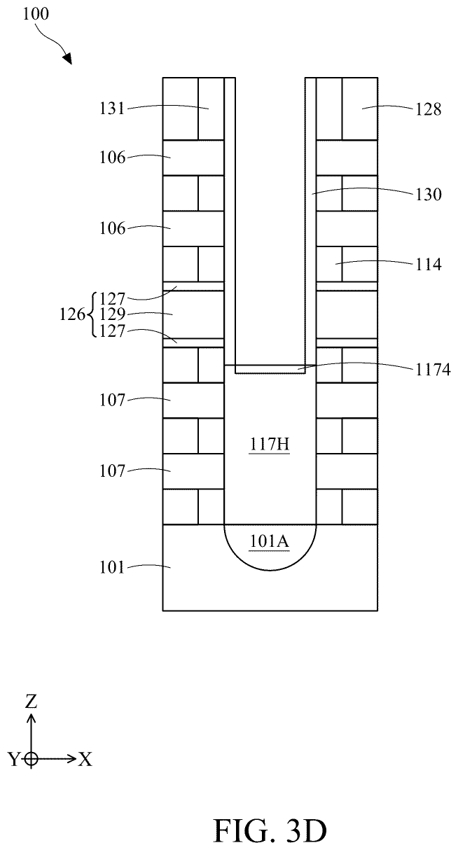

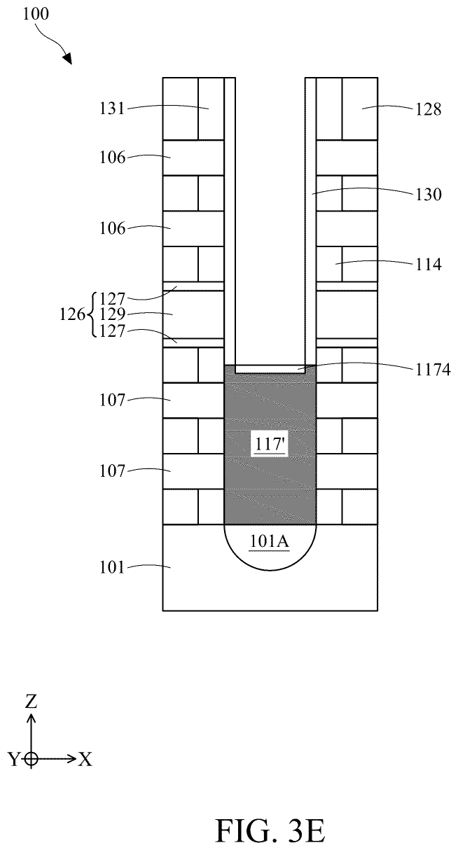

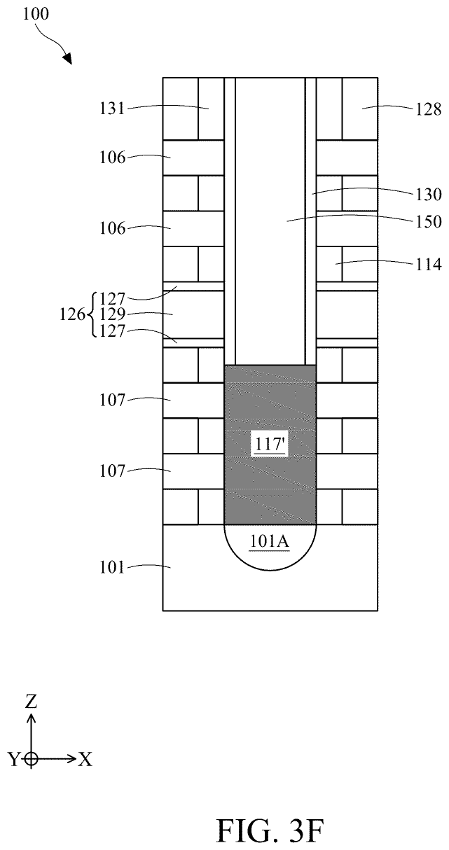

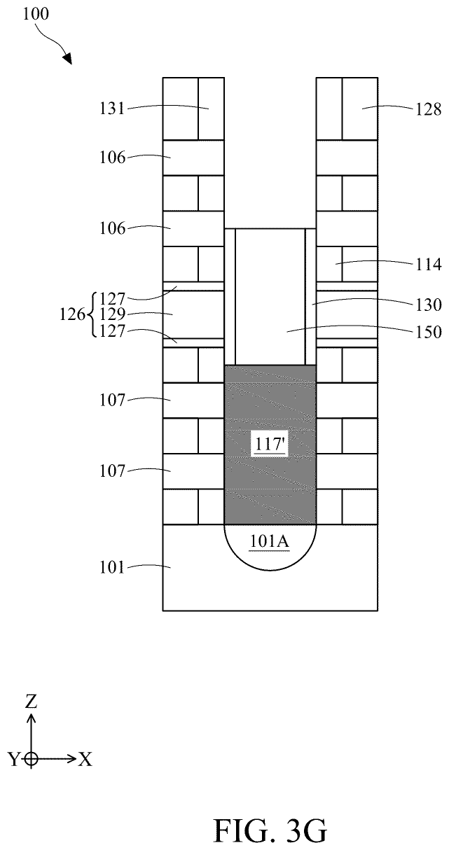

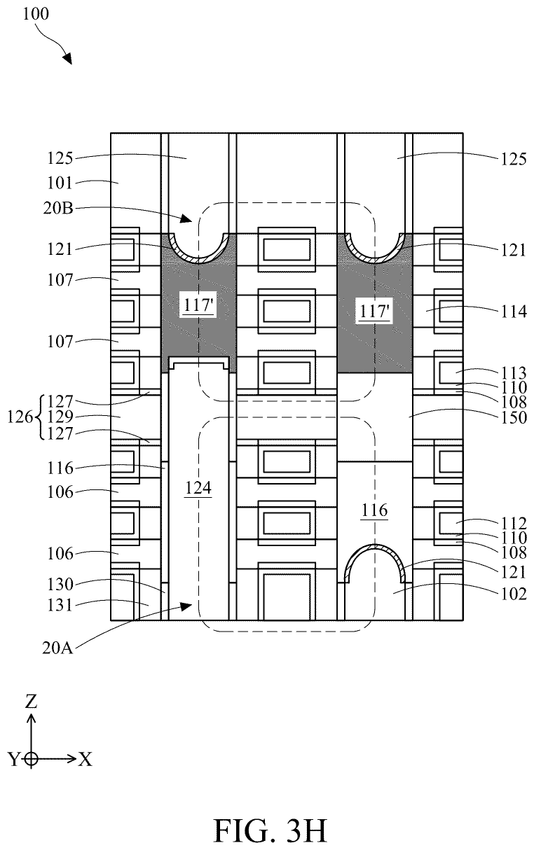

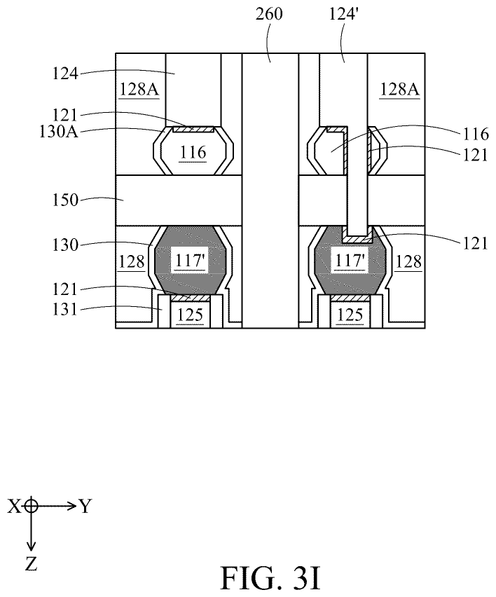

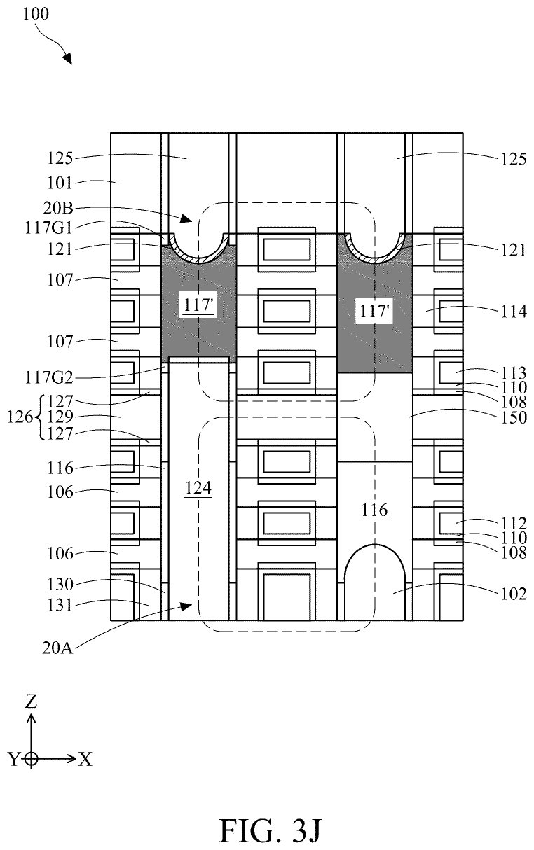

FIGS. 3A-3J are diagrammatic cross-sectional side views that depict a process for forming a device 100 in which the sacrificial source/drains 117 are replaced prior to forming the source/drains 116. Partial views of the device 100 are depicted in FIGS. 3A to 3E for simplicity of illustration.

In FIG. 3A, prior to the source/drain 116 being formed, the sacrificial source/drain 117 is formed in a source/drain opening 77 that extends through the nanostructures 106, the isolation structure 126 and the nanostructures 107 and lands on the substrate 101. In some embodiments, the source/drain opening 77 when formed initially extends into the substrate 101, such that an upper surface of the substrate 101 under the source/drain opening 77 is concave. The concave portion may be regrown with undoped silicon to form a semiconductor region 101A that can have a level upper surface that is substantially coplanar with an upper surface of the substrate 101 and a lower surface of the bottommost inner spacer 114. The semiconductor region 101A can be beneficial to provide a substantially planar surface from which the sacrificial source/drain 117 may grow in addition to growing from the side surfaces of the nanostructures 107 exposed by the source/drain opening 77.

To avoid growing the sacrificial source/drain 117 on the nanostructures 106, the dielectric layer 130 may be present on and entirely covering side surfaces of the nanostructures 106. The dielectric layer 130 may also cover the side surfaces of the semiconductor layers 127 of the isolation structure 126. For example, the dielectric layer 130 may be a thin conformal layer that extends from the sidewall spacer 131 to a level that is between upper and lower surfaces of an uppermost inner spacer 114 that is between the uppermost nanostructure 107 and the isolation structure 126.

The sacrificial source/drain 117 may be formed by a suitable epitaxial growth operation that grows material of the sacrificial source/drain 117 in the source/drain opening 77. The sacrificial source/drain 117 can be or include one or more semiconductor materials, which can include SiGe, Ge, GeSn, SiGeSn. In the sacrificial source/drain 117, concentration of germanium can be less than about 40%, less than about 30%, less than about 20% or another value. The germanium concentration of the sacrificial source/drain 117 being greater than about 40% can result in diffusion of germanium into the nanostructures 107. Epitaxial growth of semiconductor material in the source/drain openings can be performed via chemical vapor deposition (CVD), molecular beam epitaxy (MBE), or the like.

In some embodiments, dopants are introduced into the sacrificial source/drain 117 in situ, as described with reference to FIG. 1D. In some embodiments, the dopants include B, Ga, P, As or the like. In the growth process, diborane, phosphine, trimethylgallium, triethylgallium, arsine, tertiarybutylarsine or the like may be flowed in gaseous state to dope the sacrificial source/drain 117 in situ. In some embodiments, the sacrificial source/drain 117 may be doped in a subsequent operation, for example, by implantation of one or more of B, Ga, P, As or the like.

As depicted in FIG. 3B, following formation of the sacrificial source/drain 117, an interlayer dielectric (ILD) 300, an etch stop layer (ESL) 310, or both, are formed on and laterally adjacent the sacrificial source/drain 117. Then, the ILD 300 may be recessed and the ESL 310 may be broken through to expose upper surfaces of the sacrificial source/drains 117. This is depicted diagrammatically in FIG. 3B via a dashed line. For example, material of the ILD 300 above the dashed line in FIG. 3B may be removed by the recessing operation.

In FIG. 3C, following formation of the sacrificial source/drain 117, the ILD 300 and the ESL 310 and recessing of the ILD 300, a porous oxide layer 1174 is formed on the exposed upper surface of the sacrificial source/drain 117. The porous oxide layer 1174 may be similar in most respects to the porous oxide layer 1172 described with reference to FIG. 1B. In some embodiments, the porous oxide layer 1174 is substantially planar due to the planar surface of the sacrificial source/drain 117.

In FIG. 3C, an oxidation process is performed that forms the porous oxide layer 1174 over the sacrificial source/drain 117 on exposed upper surfaces thereof. Thickness of the porous oxide layer 1174 may be in a range of about 0.8 nm to about 2 nm, such as about 1 nm. Formation of the porous oxide layer 1174 may include thermal oxidation, where the SiGe sacrificial source/drain region 117 is exposed to oxygen or water vapor at high temperatures. The thermal oxidation process can cause the silicon in the SiGe alloy to react with oxygen, forming silicon dioxide (SiO2). Because germanium oxidizes differently than silicon, a less stable germanium oxide (GeOx) that can volatilize at the oxidation temperatures may be formed, affecting uniformity and quality of the porous oxide layer 1174. Namely, pores may be present in the porous oxide layer 1174 that extend entirely through the porous oxide layer 1174 such that the sacrificial source/drain region 117 is exposed at least partially through the porous oxide layer 1174. With the dielectric layer 130 in place covering the nanostructures 106, generally no oxide layer grows on the nanostructures 106 during growth of the porous oxide layer 1174 on the sacrificial source/drain 117.

In FIG. 3D, an opening 117H is formed by removing the sacrificial source/drain 117 through the porous oxide layer 1174. Removal of the sacrificial source/drain 117 may be similar in most respects as to described with reference to FIG. 1C. The sacrificial source/drain regions 117 may be removed via a suitable etching operation, which may include a chlorine-based etchant, a fluorine-based etchant, or the like. The etchant, which can be a gas, may penetrate through the porous oxide layer 1174 and etch the SiGe of the sacrificial source/drain regions 117, resulting in the sacrificial source/drain regions 117 being removed and the openings 117H being formed. The openings 117H may inherit shape of the sacrificial source/drain regions 117, as depicted in FIG. 3D. In some embodiments, as described with reference to FIGS. 2A and 2B, some overetching may occur that removes end portions of the nanostructures 107.

In FIG. 3E, the second source/drain 117′ is formed through the porous oxide layer 1174. Formation of the second source/drain 117′ may be similar in most respects to that described with reference to FIG. 1D. For example, following formation of the openings 117H, the second source/drain region 117′ is formed in the openings 117H through the porous oxide layer 1174. The replacement source/drain 117′ can be formed by a suitable epitaxial growth operation that grows material of the replacement source/drain regions 117′ in the opening 117H. The replacement source/drain 117′ can be or include one or more semiconductor materials, which can include SiGe, Ge, GeSn, SiGeSn. In the replacement source/drain 117′, concentration of germanium can be in a range of about 75% to 100% (i.e., pure Ge). Epitaxial growth of Ge or SiGe in the source/drain openings can be performed via chemical vapor deposition (CVD), molecular beam epitaxy (MBE), or the like. In CVD, gases containing the selected elements (e.g., germane for Ge, silane for Si, and optionally diborane, phosphine, TMGa, TEGa, AsH₃ or TBA for doping) are introduced into a reaction chamber. The device 100 can be heated to a high temperature, such that the gases react or decompose to form the epitaxial layer. CVD can be beneficial for good uniformity and control over layer composition. MBE can provide benefits of increased precision where the elements are evaporated in a high-vacuum environment and then condense on the heated device 100. MBE can provide excellent control over the thickness and composition of the epitaxial layer of the replacement source/drain 117′ at the atomic level, beneficial for nanoscale devices.

In CVD and MBE, the porous oxide layer 1174 is permeable to the precursor gases (e.g., germane, silane, diborane, phosphine, and the like), such that the precursor gases may react or decompose at the nanostructures 107 in the openings 117H. Namely, exposed side surfaces of end portions of the nanostructures 107 can have the semiconductor material grown thereon. In some embodiments, the dopants are introduced into the replacement source/drain 117′ in situ. In some embodiments, the dopants include B, Ga, P, As or the like. In the growth process, diborane, phosphine, trimethylgallium, triethylgallium, arsine, tertiarybutylarsine or the like may be flowed in gaseous state to dope the replacement source/drain 117′ in situ. In some embodiments, the replacement source/drain 117′ may be doped in a subsequent operation, for example, by implantation of one or more of B, Ga, P, As or the like.

In some embodiments, as described with reference to FIGS. 1A-2B, the porous oxide layer 1174 may be removed prior to forming the second source/drain 117′.

In FIG. 3F, the porous oxide layer 1174 is removed and a dielectric isolation layer 150 is formed in the source/drain opening 77 on the second source/drain 117′. In some embodiments, the dielectric isolation layer 150 is formed of a dielectric material, such as SiN, SiCN, SiCON or the like. The dielectric isolation layer 150 may be formed by a suitable deposition process, such as a PVD, CVD, ALD or the like. Following deposition of material of the dielectric isolation layer 150, excess material thereof above the source/drain opening 77 may be removed by one or more removal operations, such as a CMP. Upper surfaces of the dielectric isolation layer 150 may initially be coplanar with upper surfaces of the sidewall spacer 131 and the dielectric layer 128.

Then, in FIG. 3G, the dielectric isolation layer 150 is recessed to a level that is below the nanostructures 106 to expose the nanostructures 106 for subsequent epitaxial growth of the source/drains 116. The recessing may be by a suitable etching operation, such as a wet etch or dry etch that removes material of the dielectric isolation layer 150 without substantially attacking the nanostructures 106, the inner spacers 114 and the sidewall spacers 131. In some embodiments, the dielectric isolation layer 150 includes the same material as the dielectric layer 130, such that the dielectric layer 130 is recessed simultaneously with the dielectric isolation layer 150 to substantially the same level as the dielectric isolation layer 150. In some embodiments, when the dielectric isolation layer 150 and the dielectric layer 130 include different materials, the dielectric layer 130 can be recessed after the dielectric isolation layer 150.

Then, in FIGS. 3H and 3I, the source/drains 116 are formed adjacent to the nanostructures 106. Formation of the source/drains 116 is similar in most respects to formation of the sacrificial source/drains 117 and the source/drains 117′ described with reference to FIGS. 1A, 1D, 2B, 3A and 3E except that the source/drains 116 may be N-type source/drains 116 instead of the source/drains 117′ that are P-type source/drains 117′ that provide beneficial compressive strain to the nanostructures 107 due to the high-Ge-concentration semiconductor material thereof.

In FIGS. 3H and 3I, following formation of the source/drains 116, the source/drain contacts 124 are formed on the source/drains 116 and optionally on the source/drains 117′ via extension through the dielectric isolation layer 150. Formation of the source/drain contacts 124 may be similar in most respects to formation of the source/drain contacts 125. The source/drain contact 124 (labeled 124′ in FIG. 3I) that extends to the source/drains 117′ via extension through the dielectric layer 150 may be referred to as an MDLI (“source/drain contact interconnect” or “source/drain contact local interconnect”).

Following or prior to forming the source/drain contacts 125, as depicted in FIG. 3I, a vertical isolation structure 260 may be formed that physically isolates a first pair of source/drains 116, 117′ from a second pair of source/drains 116, 117′ that are offset from each other along the Y-axis direction. Also depicted in FIG. 31 is that the dielectric isolation layer 150 may extend along the Y-axis direction and may isolate the source/drains 116 vertically from the source/drains 117′.

FIG. 3J depicts that air gaps 117G1, 117G2 can be formed adjacent the second source/drains 117′ as described with reference to FIG. 1F. Namely, embodiments in which the dielectric isolation structure 150 is formed following formation of the replacement source/drains 117′ and prior to formation of the source/drains 116 can include the air gaps 117G1, 117G2 described with reference to FIG. 1F.

Embodiments of the present disclosure provide advantages. By forming the high-Ge-concentration second source/drain structure after forming the active gate, germanium is prevented from diffusing into the nanostructure channels and adjacent structures (e.g., the active gate) are in place, which provides additional support for increasing strain during formation of the second source/drain structure. Replacement with pure Ge or high-Ge-concentration semiconductor material (e.g., SiGe) can increase lattice constant, which increases strain and drive current. The pure Ge or high-Ge-concentration semiconductor material can also have reduced source/drain contact resistance, which can result in a boost to current output.

In some embodiments, a device includes: a plurality of first nanostructures formed in a first stack. The device also includes a plurality of second nanostructures formed in a second stack. The device also includes a first source/drain structure adjacent to the plurality of first nanostructures, the first source/drain structure including a first semiconductor having silicon and germanium. The device also includes a second source/drain structure stacked vertically over the first source/drain structure and adjacent to the plurality of second nanostructures, the second source/drain structure having a second semiconductor in which the germanium concentration exceeds the germanium concentration of the first semiconductor.

In some embodiments, a method includes: forming a first semiconductor nanostructure corresponding to a channel region of a first transistor. The method also includes forming a second semiconductor nanostructure above the first semiconductor nanostructure and corresponding to a channel region of a second transistor. The method also includes forming a first source/drain structure adjacent the first semiconductor nanostructure. The method also includes forming a sacrificial source/drain structure adjacent the second semiconductor nanostructure, the sacrificial source/drain structure including a first semiconductor having a first germanium concentration. The method also includes forming a second source/drain structure adjacent the second semiconductor nanostructure by replacing the sacrificial source/drain structure with a second semiconductor having a second germanium concentration that exceeds the first germanium concentration.

In some embodiments, a method includes: forming a first semiconductor nanostructure corresponding to a channel region of a first transistor. The method also includes forming a second semiconductor nanostructure above the first semiconductor nanostructure and corresponding to a channel region of a second transistor. The method also includes forming a first source/drain structure adjacent the first semiconductor nanostructure. The method also includes prior to the forming a first source/drain structure. The method also includes forming a sacrificial source/drain structure adjacent the second semiconductor nanostructure. The method also includes replacing the sacrificial source/drain structure with a second source/drain structure that has a germanium concentration that exceeds the germanium concentration of the sacrificial source/drain structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a plurality of first nanostructures formed in a first stack;
a plurality of second nanostructures formed in a second stack;
a first source/drain structure adjacent to the plurality of first nanostructures, the first source/drain structure including a first semiconductor having silicon and germanium; and
a second source/drain structure stacked vertically over the first source/drain structure and adjacent to the plurality of second nanostructures, the second source/drain structure having a second semiconductor in which the germanium concentration exceeds the germanium concentration of the first semiconductor.

2. The device of claim 1, wherein the germanium concentration in the second semiconductor exceeds about 75%.

3. The device of claim 2, wherein the germanium concentration in the second semiconductor is 100% excluding dopants.

4. The device of claim 1, wherein the second semiconductor includes silicon germanium, pure germanium, germanium tin or silicon germanium tin.

5. The device of claim 1, wherein the second semiconductor is doped with B, Ga, P or As at a dopant concentration in a range of about 1e19/cm³ to about 5e21/cm³.

6. The device of claim 1, wherein an air gap is positioned adjacent the second source/drain structure.

7. The device of claim 1, further comprising:
an inner spacer adjacent to one of the second nanostructures, the one of the second nanostructures having a side surface that is recessed a first distance from a side surface of the inner spacer;
wherein the second source/drain structure extends the first distance past the side surface of the inner spacer to be in contact with the one of the second nanostructures.

8. The device of claim 7, wherein the first distance is in a range of about 0.5 nm to about 2 nm.

9. The device of claim 1, further comprising:
a first silicide in contact with the first source/drain structure; and
a second silicide in contact with the second source/drain structure, the second silicide having germanium concentration that exceeds that of the first silicide.

10. The device of claim 1, wherein widths of the plurality of first nanostructures exceed widths of the plurality of second nanostructures by about 1 nanometer to about 4 nanometers.

11. A method, comprising:
forming a first semiconductor nanostructure corresponding to a channel region of a first transistor;
forming a second semiconductor nanostructure above the first semiconductor nanostructure and corresponding to a channel region of a second transistor;
forming a first source/drain structure adjacent the first semiconductor nanostructure;
forming a sacrificial source/drain structure adjacent the second semiconductor nanostructure, the sacrificial source/drain structure including a first semiconductor having a first germanium concentration; and
forming a second source/drain structure adjacent the second semiconductor nanostructure by replacing the sacrificial source/drain structure with a second semiconductor having a second germanium concentration that exceeds the first germanium concentration.

12. The method of claim 11, wherein the replacing the sacrificial source/drain structure includes:
forming a porous oxide layer on an upper surface of the sacrificial source/drain structure; and
removing the sacrificial source/drain structure by etching through the porous oxide layer.

13. The method of claim 11, wherein the replacing the sacrificial source/drain structure includes:
forming an opening by removing the sacrificial source/drain structure, the opening having a first height; and
forming the second source/drain structure by growing the second semiconductor in the opening, the second semiconductor having a second height that does not exceed the first height.

14. The method of claim 13, further comprising:
forming a source/drain contact on the second source/drain structure, an air gap being positioned between the second source/drain structure and the source/drain contact.

15. The method of claim 13, wherein the replacing the sacrificial source/drain structure includes:
forming the opening by removing the sacrificial source/drain structure;
during the removing the sacrificial source/drain structure, forming a recess by removing an end portion of the second semiconductor nanostructure; and
forming the second source/drain structure by growing the second semiconductor in the opening, including growing the second semiconductor in the recess.

16. The method of claim 11, further comprising:
prior to the forming the second source/drain structure, forming a sacrificial gate that wraps around the second semiconductor nanostructure; and
forming an active gate by replacing the sacrificial gate.

17. A method, comprising:
forming a first semiconductor nanostructure corresponding to a channel region of a first transistor;
forming a second semiconductor nanostructure above the first semiconductor nanostructure and corresponding to a channel region of a second transistor;
forming a first source/drain structure adjacent the first semiconductor nanostructure; and
prior to the forming a first source/drain structure:
forming a sacrificial source/drain structure adjacent the second semiconductor nanostructure; and
replacing the sacrificial source/drain structure with a second source/drain structure that has a germanium concentration that exceeds thea germanium concentration of the sacrificial source/drain structure.

18. The method of claim 17, wherein the replacing the sacrificial source/drain structure comprises:
forming a porous layer on the sacrificial source/drain structure;
forming an opening by removing the sacrificial source/drain structure through the porous layer; and
forming the second source/drain structure in the opening.

19. The method of claim 18, wherein:
the forming the opening includes forming a recess by recessing the second semiconductor nanostructure; and
the forming the second source/drain structure includes forming the second source/drain structure in the recess.

20. The method of claim 18, wherein the forming the second source/drain structure includes partially filling the opening with the second source/drain structure, the method further comprising:
forming a source/drain contact on the second source/drain structure, an air gap being present between the source/drain contact and the second source/drain structure.
